(19) United States
(12) Patent Application Publication
(10) Pub. No.: US 2026/0143677 A1
(43) Pub. Date: May 21, 2026

(54) CAPACITOR STRUCTURE AND SEMICONDUCTOR DEVICE INCLUDING THE CAPACITOR STRUCTURE

(71) Applicant: Samsung Electronics Co., Ltd., Suwon-si (KR)

(72) Inventors: Jungmin Park, Suwon-si (KR); Jihoon An, Suwon-si (KR); Jungoo Kang, Suwon-si (KR); Beomjong Kim, Suwon-si (KR); Hyungsuk Jung, Suwon-si (KR); Hongsik Chae, Suwon-si (KR)

(21) Appl. No.: 19/375,363

(22) Filed: Oct. 31, 2025

(30) Foreign Application Priority Data
Nov. 18, 2024 (KR) 10-2024-0163993

(51) Int. Cl. H10B 12/00

(52) U.S. Cl. CPC H10B 12/315; H10B 12/033

(57) ABSTRACT

The capacitor structure include a lower electrode structure comprising a lower electrode including a first material containing a metal and extending in a first direction and an insertion layer including a second material having a coefficient of thermal expansion (CTE) lower than a CTE of the first material and extending in the first direction through the lower electrode, a dielectric pattern on a surface of the lower electrode structure and an upper electrode on a surface of the dielectric pattern.

### BRIEF DESCRIPTION OF THE DRAWINGS

FIGS. 1, 2A, 2B and 2C are cross-sectional views illustrating a capacitor structure in accordance with example embodiments.

FIGS. 3, 4, 5, 6A, 6B, 6C, 7, 8, and 9 are cross-sectional views illustrating a method of forming a capacitor structure in accordance with example embodiments.

FIG. 10 is a plan view illustrating a semiconductor device in accordance with example embodiments, and FIG. 11 is a cross-sectional view taken along line A-A′ of FIG. 10.

FIGS. 12 to 27 are plan views and cross-sectional views illustrating a method of manufacturing a semiconductor device according to example embodiments.

FIG. 28 is a graph illustrating changes in stress magnitude over time when an oxide layer is formed on a surface of a titanium nitride layer.

FIG. 29 is a graph showing XRD (X-ray Diffraction) experimental results for a titanium nitride layer according to a comparative example and a titanium nitride layer including an insertion layer and/or an insertion pattern in accordance with example embodiments.

FIG. 30 is a bar graph showing stress of titanium nitride layers with a dielectric layer formed on surfaces of the titanium nitride layer according to a comparative example and the titanium nitride layer in accordance with example embodiments.

### DETAILED DESCRIPTION

The above and other aspects and features of the capacitor structures and the methods of manufacturing the same, the semiconductor devices including the capacitor structures and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

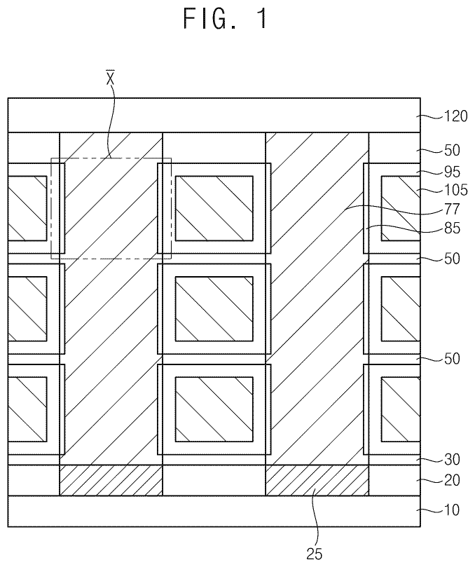

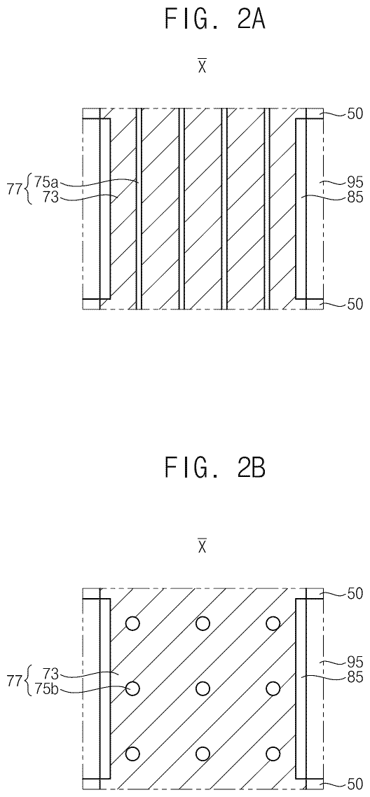

FIG. 1 is a cross-sectional view illustrating a capacitor structure in accordance with example embodiments, and FIGS. 2A, 2B and 2C are enlarged cross-sectional views of region X of FIG. 1.

Referring to FIGS. 1, 2A, 2B and 2C, the capacitor structure may include a lower electrode structure 77, an interface layer 85, a dielectric pattern 95, and an upper electrode 105 on a substrate 10. The capacitor structure may further include an upper electrode plate 120, a first conductive pattern 25, an insulating interlayer 20, a first etch stop layer 30, and a support layer 50.

The substrate 10 may include a semiconductor material, e.g., silicon, germanium, silicon-germanium, etc., or III-V semiconductor compounds, e.g., GaP, GaAs, GaSb, etc. In some embodiments, the substrate 10 may include a silicon-on-insulator (SOI) substrate or a germanium-on-insulator (GOI) substrate.

The insulating interlayer 20 containing the first conductive pattern 25 therein may be disposed on the substrate 10. Upper and lower surfaces of the insulating interlayer 20 may be coplanar with upper and lower surfaces of the first conductive pattern 25, respectively. The first conductive pattern 25 may include, e.g., a contact plug, a landing pad, etc., and a plurality of first conductive patterns 25 may be spaced apart from each other in a horizontal direction substantially parallel to an upper surface of the substrate 10 on the substrate 10. The first conductive pattern 25 may include, e.g., a metal, a metal nitride, a metal silicide, polysilicon doped with impurities, etc.

The insulating interlayer 20 may include an oxide, e.g., silicon oxide or a low-k dielectric material.

The first etch stop layer 30 may be disposed on the insulating interlayer 20. The first etch stop layer 30 may contact the upper surface of the insulating interlayer 20. The first etch stop layer 30 may include an insulating nitride, e.g., silicon nitride, silicon boronitride, silicon carbonitride, etc.

The lower electrode structure 77 may extend through the first etch stop layer 30, and may contact an upper surface of a corresponding one of the first conductive patterns 25. The lower electrode structure 77 may have a shape of a pillar extending in a vertical direction substantially perpendicular to the upper surface of the substrate 10.

In example embodiments, the lower electrode structure 77 may include a lower electrode 73 and an insertion layer 75a, and/or an insertion pattern 75b. The lower electrode 73 may include a first material including a metal or a metal nitride having a tensile stress, e.g., titanium nitride (TiN), and each of the insertion layer 75a and the insertion pattern 75b may include a second material having a coefficient of thermal expansion (CTE) smaller than a coefficient of thermal expansion (CTE) of the first material, or a third material having an ionic radius of a central atom smaller than an ionic radius of a central atom of the first material.

In example embodiments, the second material may include a material having a CTE less than about 8*10⁻⁶/K, e.g., SiO₂, Al₂O₃, Ta₂O₃, Nb₂O₅, ZnO, ZrO₂, HfO₂, MgO, SiN, SiC, AlN, TaN, HfN, WC, etc. The third material may include, e.g., V⁺⁵, Cr⁺⁵, Mn⁺⁷, Fe⁺³, Ga⁺³, Ge⁺⁴, Al⁺³, Si⁺⁴, Mg⁺², Mo⁺⁶, Ru⁺⁸, etc., and oxides thereof. For example, if the first material is titanium nitride (TiN), the ionic radius of the third material may be less than about 0.7 Å.

In an example embodiment, as illustrated in FIG. 2A, the lower electrode structure 77 may include the lower electrode 73 including the first material and extending in the vertical direction, and the insertion layer 75a extending in the vertical direction through the lower electrode 73. FIG. 2A shows that four insertion layers 75a are spaced apart from each other in the horizontal direction, however, the inventive concept is not limited thereto, and a plurality of insertion layers 75a may be spaced apart from each other in the horizontal direction.

In another example embodiment, as illustrated in FIG. 2B, the lower electrode structure 77 may include the lower electrode 73 including the first material and extending in the vertical direction, and the insertion patterns 75b dispersed in the lower electrode 73 and including the second material and/or the third material. That is, the lower electrode structure 77 may include the lower electrode 73 in which the second material and/or the third material are dispersed.

In another example embodiment, as illustrated in FIG. 2C, the lower electrode structure 77 may include the lower electrode 73 including the first material and extending in the vertical direction, the insertion patterns 75b dispersed in the lower electrode 73 and including the second material and/or the third material, and the insertion layer 75a extending in the vertical direction through the lower electrode 73. FIG. 2C shows that three insertion layers 75a are spaced apart from each other in the horizontal direction, however, the inventive concept is not limited thereto, and a plurality of insertion layers 75a may be spaced apart from each other in the horizontal direction.

In example embodiments, a thickness of the lower electrode structure 77 in the horizontal direction may be about 50 Å to about 200 Å, and a weight ratio of the second material and/or the third material included in the lower electrode structure 77 may be less than about 30% with respect to the entire lower electrode structure 77. A thickness of the insertion layer 75a in the horizontal direction may be about 1 Å to about 10 Å.

The interface layer 85 may be disposed on a portion of a sidewall of the lower electrode structure 77 contacting the dielectric pattern 95. For example, the interface layer 85 may be provided between the lower electrode structure 77 and the dielectric pattern 95.

In example embodiments, the interface layer 85 may include, e.g., an oxide of the first material, and may further include an oxide of the second material and/or an oxide of the third material.

The support layer 50 may be disposed on the sidewall of each of the lower electrode structures 77, and may have a shape of a plate having lower and upper surfaces substantially parallel to the upper surface of the substrate 10. For example, the support layer 50 may contact side surfaces of each of the lower electrode structures 77. In example embodiments, a plurality of support layers 50 may be spaced apart from each other in the vertical direction. For example, the plurality of support layers 50 may be disposed between adjacent dielectric patterns 95.

In example embodiments, the support layer 50 may include an insulating nitride, e.g., silicon nitride (SiN), silicon boron nitride (SiBN), silicon carbon nitride (SiCN), etc.

The dielectric pattern 95 may contact a sidewall the interface layer 85 between the first etch stop layer 30 and a lowermost one of the support layers 50 and between the support layers 50. The dielectric pattern 95 may contact an upper surface of the first etch stop layer 30, a lower surface of an uppermost one of the support layers 50, and upper and lower surfaces of each of other ones of the support layers 50 excluding the uppermost one thereof.

The dielectric pattern 95 may include a metal with 4 valence electrons, e.g., hafnium or zirconium or a high-K dielectric material.

The upper electrode 105 may have a surface covered by the dielectric pattern 95, and may be disposed between the first etch stop layer 30 and the lowermost one of the support layers 50, and between the support layers 50. In example embodiments, the dielectric pattern 95 may contact upper, lower, and side surfaces of the upper electrodes 105.

The upper electrode 105 may include substantially the same material as the lower electrode 73, that is, the first material, or may include a different material from the lower electrode 73.

The upper electrode plate 120 may be disposed on the lower electrode structure 77 and the uppermost one of the support layers 50, and may include, e.g., silicon-germanium doped with impurities. The upper electrode plate 120 may contact the lower electrode structure 77 and the uppermost one of the support layers 50.

As illustrated above, the capacitor structure may include the lower electrode structure 77, the interface layer 85 and the dielectric pattern 95 sequentially stacked on the portion of the sidewall of the lower electrode structure 77. The lower electrode structure 77 may include the first material including the metal having the tensile stress, the second material having the CTE smaller than the CTE of the first material and/or the third material having the ionic radius of the central atom smaller than the ionic radius of the central atom of the first material,

If the lower electrode structure 77 does not include the second material and/or the third material, and only includes the first material, the lower electrode structure 77 may have a relatively high first tensile stress. With the interface layer 85 and the dielectric pattern 95 disposed on the sidewall of the lower electrode structure 77, the interface layer 85 and the dielectric pattern 95 may collectively have a compressive stress, so that the lower electrode structure 77 may bend due to a difference between the first tensile stress and the compressive stress. Thus, the lower electrode structure 77 and the upper electrode 105 adjacent to each other may contact each other, which may cause defects.

However, in example embodiments, the lower electrode structure 77 may further include the second material and/or the third material, and thus the lower electrode structure 77 may have a second tensile stress that is lower than the first tensile stress, so that a difference between the second tensile stress and the compressive stress may be lower than the difference between the first tensile stress and the compressive stress, when the interface layer 85 and the dielectric pattern 95 are disposed on the sidewall of the lower electrode structure 77. Thus, the defects of the bending of the lower electrode structure 77 due to the contacting the adjacent upper electrode 105 may be prevented or reduced, and the capacitor structure including the lower electrode structure 77 may have improved electrical characteristics.

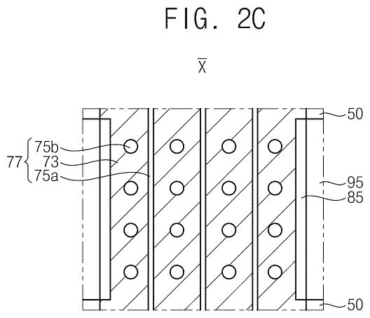

FIGS. 3 to 9 are cross-sectional views illustrating a method of forming a capacitor structure in accordance with example embodiments.

Referring to FIG. 3, an insulating interlayer 20 containing a first conductive pattern 25 may be formed on a substrate 10, a first etch stop layer 30 may be formed on the insulating interlayer 20 and the first conductive patterns 25, and a mold layer 40 and a support layer 50 may be alternately and repeatedly stacked on the first etch stop layer 30.

In example embodiments, a plurality of first conductive patterns 25 may be spaced apart from each other in the horizontal direction.

The mold layers 40 may include an oxide, e.g., silicon oxide or a low-k dielectric material.

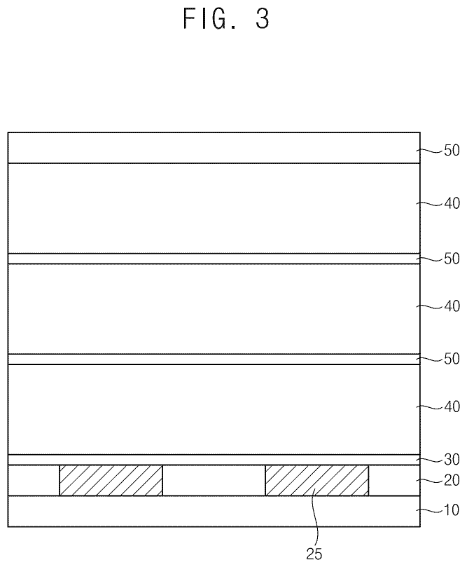

Referring to FIG. 4, first openings 55 may be formed through the support layers 50, the mold layers 40, and the first etch stop layer 30 to expose an upper surface of each of the first conductive patterns 25.

In example embodiments, the first openings 55 may be formed by forming an etching mask on an uppermost one of the support layers 50, and performing a dry etch process using the etching mask.

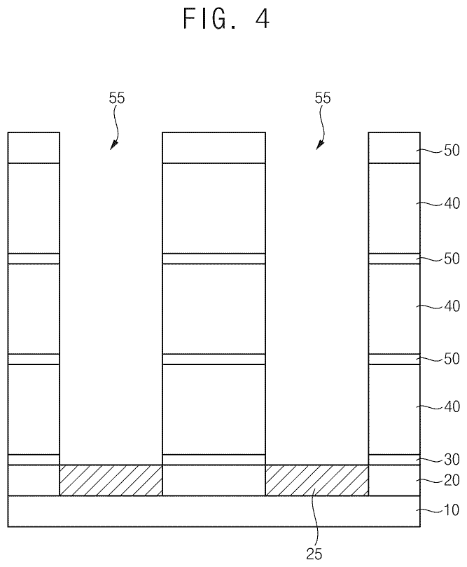

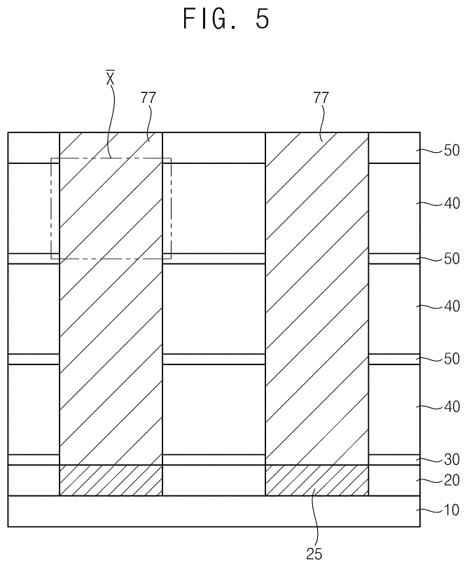

Referring to FIG. 5 and FIGS. 6A, 6B, and 6C, a lower electrode layer filling the first opening 55 may be formed on the upper surface of the first conductive pattern 25 and the upper surface of the uppermost one of the support layers 50 by performing a deposition process, and the lower electrode layer may be planarized until the upper surface of the uppermost one of the support layers 50 is exposed, thus a lower electrode structure 77 may be formed in each of the first openings 55.

The planarization process may include, e.g., a chemical mechanical polishing (CMP) process and/or an etch back process.

The deposition process may include, e.g., an atomic layer deposition (ALD) process, and the ALD process may be performed using a first source gas for forming a first material including a metal or a metal nitride having a tensile stress, e.g., titanium nitride (TiN), and a second source gas for forming at least one of a second material having a CTE smaller than a CTE of the first material and a third material having an ionic radius of a central atom smaller than an ionic radius of a central atom of the first material.

In an example embodiment, the ALD process may be performed using the first source gas and the second source gas sequentially. As illustrated in FIG. 6A, the lower electrode structure 77 may include a lower electrode 73 including the first material and extending in the vertical direction, and an insertion layer 75a extending in the vertical direction through the lower electrode 73. FIG. 6A shows that four insertion layers 75a are spaced apart from each other in the horizontal direction, however the inventive concept may not be limited thereto, and a plurality of insertion layers 75a may be spaced apart from each other in the horizontal direction.

In another example embodiment, the ALD process may be performed using the first source gas and the second source gas simultaneously. As illustrated in FIG. 6B, the lower electrode structure 77 may include the lower electrode 73 including the first material and extending in the vertical direction, and insertion patterns 75b including the second material and/or the third material and dispersed in the lower electrode 73. The lower electrode structure 77 may be formed by dispersing the second material and/or the third material in the lower electrode 73.

In another example embodiment, the ALD process may be performed using a mixture of the first source gas and the second source gas. As illustrated in FIG. 6C, the lower electrode structure 77 may include a lower electrode 73 including the first material and extending in the vertical direction, insertion patterns 75b dispersed in the lower electrode 73 and including the second material and/or the third material, and an insertion layer 75a extending in the vertical direction through the lower electrode 73. FIG. 6C shows that three insertion layers 75a may be spaced apart from each other in the horizontal direction, however the inventive concept may not be limited thereto, and a plurality of insertion layers 75a may be spaced apart from each other in the horizontal direction.

In example embodiments, a tensile stress may occur in the lower electrode structure 77. The tensile stress of the lower electrode structure 77 may be lower than a tensile stress of a lower electrode structure including only the first material.

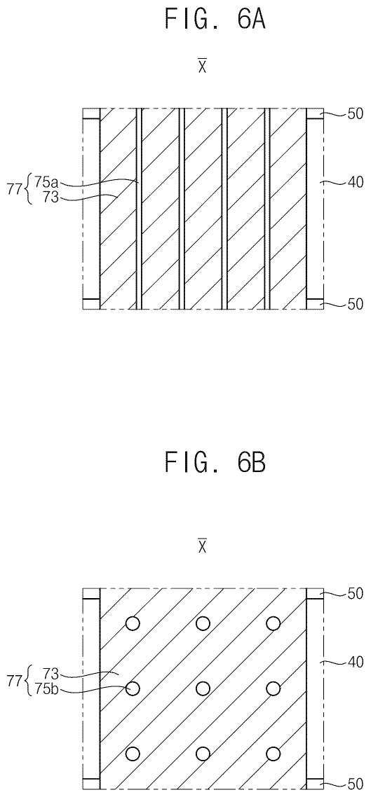

Referring to FIG. 7, a second opening exposing the upper surface of the first etch stop layer 30 may be formed by partially removing the support layers 50 and the mold layers 40, and the mold layers 40 may be removed through the second opening.

In example embodiments, the mold layers 40 may be removed by a wet etching process, and as the wet etching process is performed, third openings 80 may be formed exposing a sidewall of the lower electrode structure 77. The support layers 50 may remain on the sidewall of each lower electrode structure 77.

The upper surface of the first etch stop layer 30 and a surface of each support layer 50 may also be exposed by the third openings 80.

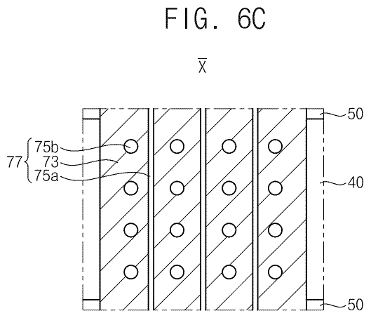

Referring to FIG. 8, an oxidation process by, e.g., supplying ozone (O₃) to the sidewall of the lower electrode structure 77 exposed by the third openings 80 may be performed to form an interface layer 85.

In example embodiments, the interface layer 85 may include, e.g., an oxide of the first material, and may further include an oxide of the second material and/or an oxide of the third material.

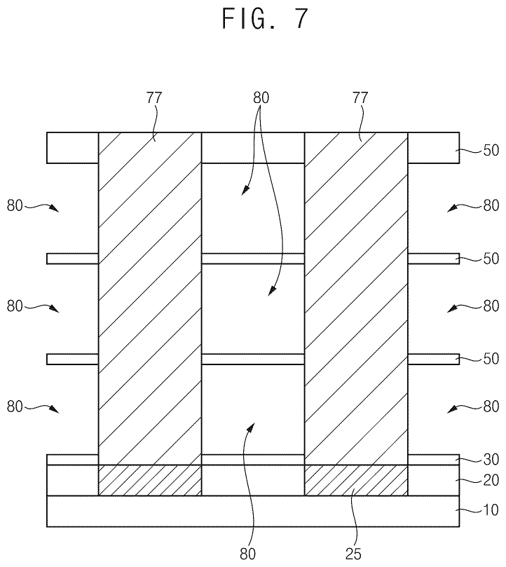

Referring to FIG. 9, a dielectric layer 90 may be formed on a sidewall of the interface layer 85, the upper surface of the first etch stop layer 30, and the surface of each of the support layers 50, and an upper electrode layer 100 may be formed on the dielectric layer 90 to fill the remaining portion of the third openings 80.

The dielectric layer 90 may include a metal oxide, e.g., hafnium oxide, zirconium oxide, etc., or a high-k material.

The dielectric layer 90 and the upper electrode layer 100 may also be stacked on the upper surface of the lower electrode structure 77 and the upper surface of the uppermost one of the support layers 50.

In example embodiments, a compressive stress may occur in the lower electrode structure 77, the dielectric layer 90, and the upper electrode layer 100.

Referring back to FIGS. 1 and 2, portions of the dielectric layer 90 and the upper electrode layer 100 sequentially stacked on the upper surface of the lower electrode structure 77 and the upper surface of the uppermost one of the support layers 50 may be removed.

Thus, the dielectric layer 90 and the upper electrode layer 100 may remain as the dielectric pattern 95 and the upper electrode 105, respectively, in the third opening 80.

The lower electrode structure 77, the dielectric pattern 95 and the upper electrode 105 may collectively form a capacitor.

An upper electrode plate 120 may be formed on the capacitor.

As illustrated above, the capacitor may be formed by forming the lower electrode structure 77, oxidizing the sidewall of the lower electrode structure 77 to form the interface layer 85, and sequentially forming the dielectric layer 90 and the upper electrode layer 100 on the interface layer 85. During the ALD process for forming the lower electrode structure 77, the second source gas of the first material having the CTE smaller than the CTE of the first material and/or the third material having the ionic radius of the central atom smaller than the ionic radius of the central atom of the first material may be used with the first source gas of the first material having the tensile stress, and thus, the lower electrode structure 77 may include not only the first material, but also the second material and/or the third material.

If the lower electrode structure 77 is formed only of the first material without including the second material and/or the third material, a relatively high first tensile stress may occur in the lower electrode structure 77, and a compressive stress may occur in the interface layer 85 and the dielectric layer 90 that may be formed after and the lower electrode structure 77. Thus, the lower electrode structure 77 may bend due to the difference between the first tensile stress and the compressive stress, so that the lower electrode structure 77 may contact the upper electrode 105 adjacent thereto, which may cause defects.

However, in example embodiments, the lower electrode structure 77 may include the second material and/or the third material, so that a relatively low second tensile stress may occur in the lower electrode structure 77 compared to the first tensile stress. Thus, the difference between the second tensile stress and the compressive stress occurring in the interface layer 85 and the dielectric layer 90 that may be formed after and the lower electrode structure 77 may be reduced. Accordingly, the defects in which the lower electrode structure 77 bends and contacts the upper electrode 105 may be prevented, and the capacitor structure including the lower electrode structure 77 may have improved electrical characteristics.

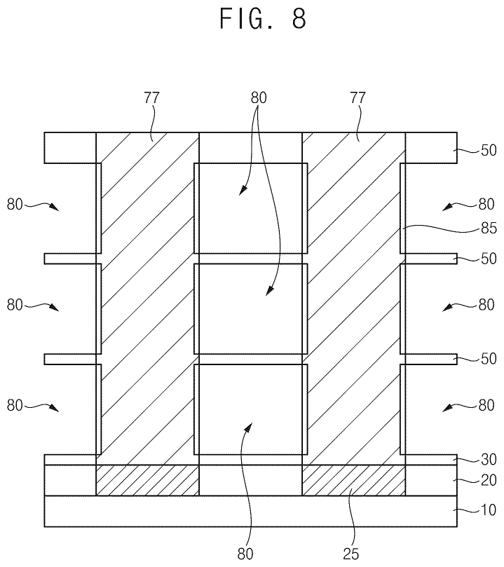

FIG. 10 is a plan view illustrating a semiconductor device in accordance with example embodiments, and FIG. 11 is a cross-sectional view taken along line A-A′ of FIG. 10.

This semiconductor device may be an application of a capacitor structure illustrated with reference to FIGS. 1 and 2 to a DRAM device, and thus repeated explanations on the capacitor structure are omitted herein.

Hereinafter, two directions among horizontal directions that are substantially parallel to an upper surface of a substrate 300, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 300 may be referred to as a vertical direction.

Referring to FIGS. 10 and 11, the semiconductor device may include an active pattern 305, a gate structure 360, a bit line structure 595, a contact plug structure, and the capacitor structure on the substrate 300.

The semiconductor device may further include an isolation pattern 310, a spacer structure 665, a fourth spacer 690, a second capping pattern 685, first and second insulation pattern structures 435 and 790, fourth and fifth insulation patterns 610 and 620, and a metal silicide pattern 700.

The active pattern 305 may extend in the third direction D3, and a plurality of active patterns 305 may be spaced apart from each other in the first and second directions D1 and D2. A sidewall of the active pattern 305 may be covered by the isolation pattern 310. The active pattern 305 may include substantially the same material as the substrate 300, and the isolation pattern 310 may include an oxide, e.g., silicon oxide.

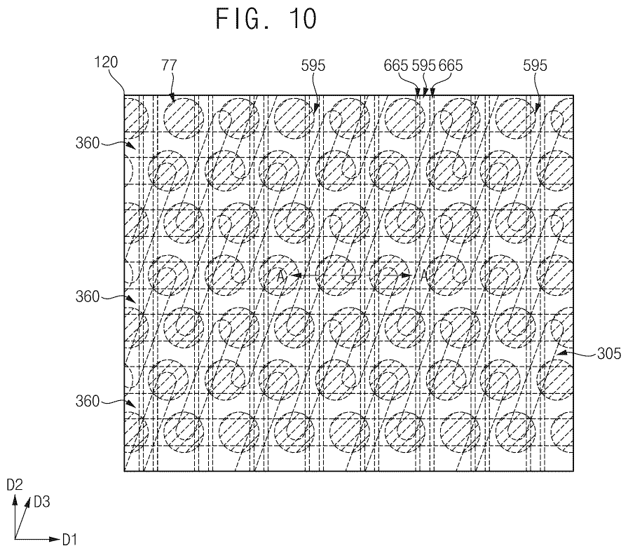

Referring to FIGS. 10 and 11 together with FIG. 13, the gate structure 360 may be formed in a second recess extending in the first direction D1 through upper portions of the active pattern 305 and the isolation pattern 310. The gate structure 360 may include a first gate insulation pattern 330 on a bottom and a sidewall of the second recess, a first gate electrode 340 on a portion of the first gate insulation pattern 330 on the bottom and a lower sidewall of the second recess, and a gate mask 350 on the first gate electrode 340 and filling an upper portion of the second recess.

The first gate insulation pattern 330 may include an oxide, e.g., silicon oxide, the first gate electrode 340 may include, e.g., a metal, a metal nitride, a metal silicide, etc., and the gate mask 350 may include an insulating nitride, e.g., silicon nitride.

In example embodiments, the gate structure 360 may extend lengthwise in the first direction D1, and a plurality of gate structures 360 may be spaced apart from each other in the second direction D2.

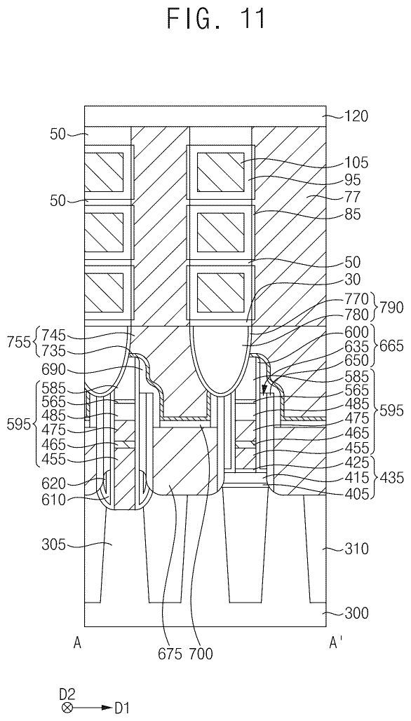

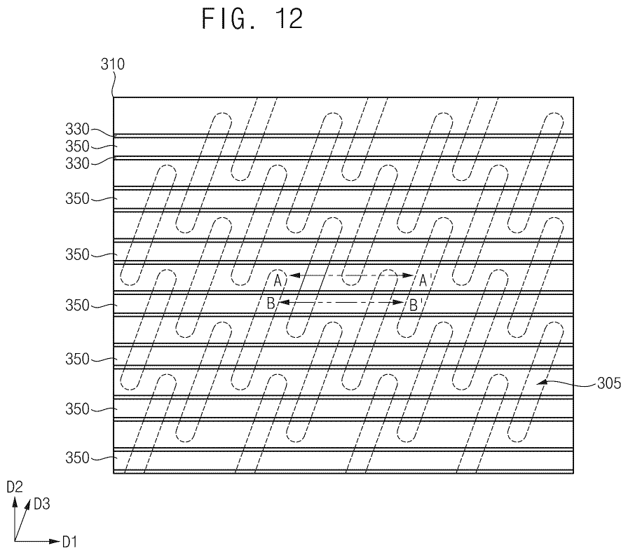

Referring to FIGS. 10 and 11 together with FIGS. 14 and 15, a fourth opening 440 extending through an insulation layer structure 430 and exposing upper surfaces of the active pattern 305, the isolation pattern 310 and the gate mask 350 of the gate structure 360 may be formed, and an upper surface of a central portion in the third direction D3 of the active pattern 305 may be exposed by the fourth opening 440.

In example embodiments, an area of a bottom of the fourth opening 440 may be greater than an area of the upper surface of the active pattern 305. Thus, the fourth opening 440 may also expose an upper surface of a portion of the isolation pattern 310 adjacent to the active pattern 305. Additionally, the fourth opening 440 may extend through upper portions of the active pattern 305 and the portion of the isolation pattern 310 adjacent thereto, and thus the bottom of the fourth opening 440 may be lower than an upper surface of each of opposite edge portions in the third direction D3 of the active pattern 305.

The bit line structure 595 may include a second conductive pattern 455, a first barrier pattern 465, a third conductive pattern 475, a first mask 485, a second etch stop pattern 565 and a first capping pattern 585 sequentially stacked in the vertical direction on the fourth opening 440 or the first insulation pattern structure 435. The second conductive pattern 455, the first barrier pattern 465 and the third conductive pattern 475 may collectively form a conductive structure, and the first mask 485, the second etch stop pattern 565 and the first capping pattern 585 may collectively form an insulation structure.

The second conductive pattern 455 may include, e.g., doped polysilicon, the first barrier pattern 465 may include a metal nitride, e.g., titanium nitride, or a metal silicon nitride, e.g., titanium silicon nitride, the third conductive pattern 475 may include a metal, e.g., tungsten, and each of the first mask 485, the second etch stop pattern 565 and the first capping pattern 585 may include an insulating nitride, e.g., silicon nitride.

In example embodiments, the bit line structure 595 may extend lengthwise in the second direction D2 on the substrate 300, and a plurality of bit line structures 595 may be spaced apart from each other in the first direction D1.

The fourth and fifth insulation patterns 610 and 620 may be formed in the fourth opening 440, and may contact a lower sidewall of the bit line structure 595. The fourth insulation pattern 610 may include an oxide, e.g., silicon oxide, and the fifth insulation pattern 620 may include an insulating nitride, e.g., silicon nitride.

The first insulation pattern structure 435 may be formed on the active pattern 305 and the isolation pattern 310 under the bit line structure 595, and may include first, second and third insulation patterns 405, 415 and 425 sequentially stacked in the vertical direction. The first and third insulation patterns 405 and 425 may include an oxide, e.g., silicon oxide, and the second insulation pattern 415 may include an insulating nitride, e.g., silicon nitride.

The contact plug structure may include a lower contact plug 675, a metal silicide pattern 700 and an upper contact plug 755 sequentially stacked in the vertical direction on the active pattern 305 and the isolation pattern 310.

The lower contact plug 675 may contact the upper surface of each of opposite edge portions in the third direction D3 of the active pattern 305. In example embodiments, a plurality of lower contact plugs 675 may be spaced apart from each other in the second direction D2, and a second capping pattern 685 may be formed between neighboring ones of the lower contact plugs 675 in the second direction D2. The second capping pattern 685 may include an insulating nitride, e.g., silicon nitride.

The lower contact plug 675 may include, e.g., doped polysilicon, the metal silicide pattern 700 may include, e.g., titanium silicide, cobalt silicide, nickel silicide, etc.

The upper contact plug 755 may include a second metal pattern 745 and a second barrier pattern 735 covering a lower surface of the second metal pattern 745. The second metal pattern 745 may include a metal, e.g., tungsten, and the second barrier pattern 735 may include a metal nitride, e.g., titanium nitride.

In example embodiments, a plurality of upper contact plugs 755 may be spaced apart from each other in the first and second directions D1 and D2, and may be arranged in a honeycomb pattern or a lattice pattern in a plan view. Each of the upper contact plugs 755 may have a shape of, e.g., a circle, an ellipse, or a polygon in a plan view.

The spacer structure 665 may include a first spacer 600 covering sidewalls of the bit line structure 595 and the third insulation pattern 425, an air spacer 635 on a lower outer sidewall of the first spacer 600, and a third spacer 650 on an outer sidewall of the air spacer 635, a sidewall of the first insulation pattern structure 435, and upper surfaces of the fourth and fifth insulation patterns 610 and 620.

Each of the first and third spacers 600 and 650 may include an insulating nitride, e.g., silicon nitride, and the air spacer 635 may include air. The term “air” as discussed herein, may refer to atmospheric air, or other gases that may be present during the manufacturing process.

The fourth spacer 690 may be formed on an outer sidewall of a portion of the first spacer 600 on an upper sidewall of the bit line structure 595, and may cover an upper end of the air spacer 635 and an upper surface of the third spacer 650. The fourth spacer 690 may include an insulating nitride, e.g., silicon nitride.

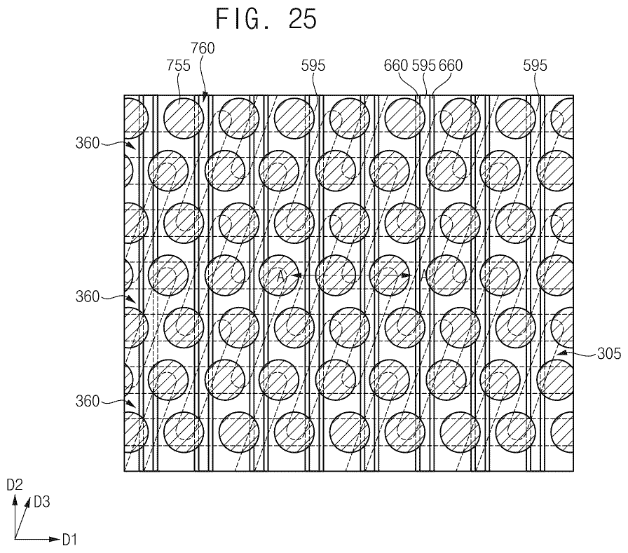

Referring to FIGS. 10 and 11 together with FIGS. 25 to 27, the second insulation pattern structure 790 may include a sixth insulation pattern 770 on an inner wall of a ninth opening 760, which may extend through the upper contact plug 755, a portion of the insulation structure of the bit line structure 595 and portions of the first, third and fourth spacers 600, 650 and 690 and surround the upper contact plug 755 in a plan view, and a seventh insulation pattern 780 on the sixth insulation pattern 770 and fill a remaining portion of the ninth opening 760. The upper end of the air spacer 635 may be closed by the sixth insulation pattern 770.

Each of the sixth and seventh insulation patterns 770 and 780 may include an insulating nitride, e.g., silicon nitride.

The first etch stop layer 30 may be formed on the sixth and seventh insulation patterns 770 and 780, the upper contact plug 755 and the second capping pattern 685.

The lower electrode structure 77 in the capacitor may contact an upper surface of the upper contact plug 755.

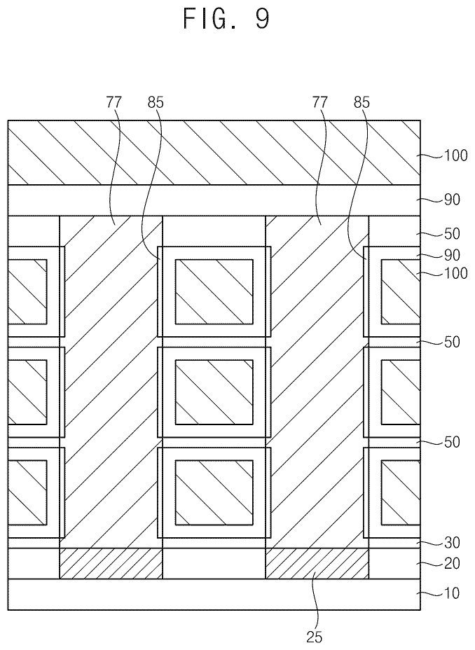

FIGS. 12 to 27 are plan views and cross-sectional views illustrating a method of manufacturing a semiconductor device in accordance with example embodiments. Specifically, FIGS. 12, 14, 17, 21 and 25 are the plan views, FIG. 13 includes cross-sectional views taken along lines A-A′ and B-B′ of FIG. 12, and FIGS. 15-16, 18-20, 22-24 and 26-27 are cross-sectional views taken along line A-A′ of corresponding plan views.

The method of manufacturing the semiconductor device is an application of the method of forming the capacitor structure described with reference to FIGS. 1 to 9 to a method of manufacturing a DRAM device, and repeated explanations of the method of forming the capacitor structure are omitted herein.

Referring to FIGS. 12 and 13, an upper portion of a substrate 300 may be removed to form a first recess, and an isolation pattern 310 may be formed in the first recess.

As the isolation pattern 310 is formed on the substrate 300, an active pattern 305 of which a sidewall is covered by the isolation pattern 310 may be defined.

The active pattern 305 and the isolation pattern 310 on the substrate 300 may be partially etched to form a second recess extending in the first direction D1, and a gate structure 360 may be formed in the second recess. In example embodiments, the gate structure 360 may extend lengthwise in the first direction D1, and a plurality of gate structures may be spaced apart from each other in the second direction D2.

Referring to FIGS. 14 and 15, an insulating layer structure 430 may be formed on the active pattern 305, the isolation pattern 310, and the gate structure 360. The insulating layer structure 430 may include first to third insulating layers 400, 410, and 420 sequentially stacked.

The insulating layer structure 430 may be patterned, and the active pattern 305, the isolation pattern 310, and the gate mask 350 included in the gate structure 360 may be partially etched using the patterned insulating layer structure 430 as an etching mask to form a fourth opening 440. In example embodiments, the insulating layer structure 430 may have a circular shape or an elliptical shape in a plan view, and a plurality of insulating layer structures 430 may be spaced apart from each other in the first and second directions D1 and D2. Each of the insulating layer structures 430 may overlap end portions of ones of the active patterns 305 neighboring in the third direction D3, which may face each other, in a vertical direction substantially orthogonal to the upper surface of the substrate 300.

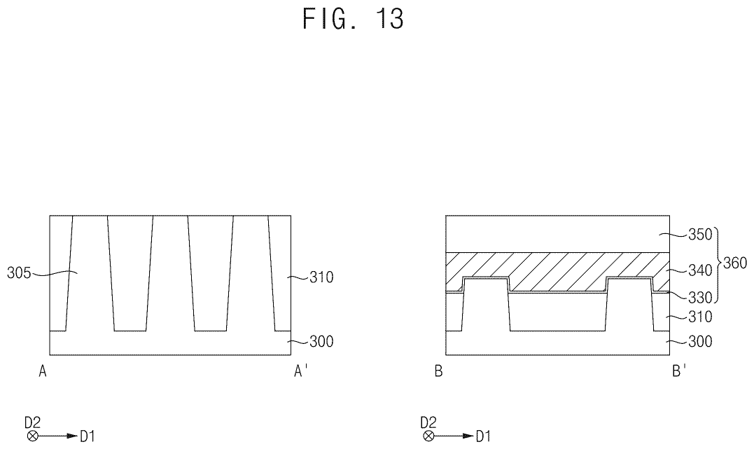

Referring to FIG. 16, a first conductive layer 450, a first barrier layer 460, a second conductive layer 470 and a first mask layer 480 may be sequentially stacked on the insulating layer structure 430, and the active pattern 305, the isolation pattern 310 and the gate structure 360 exposed by the fourth opening 440. The first conductive layer 450 may fill the fourth opening 440.

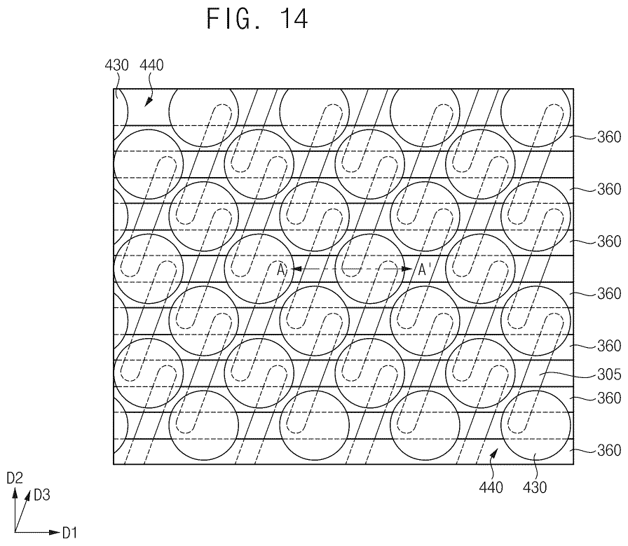

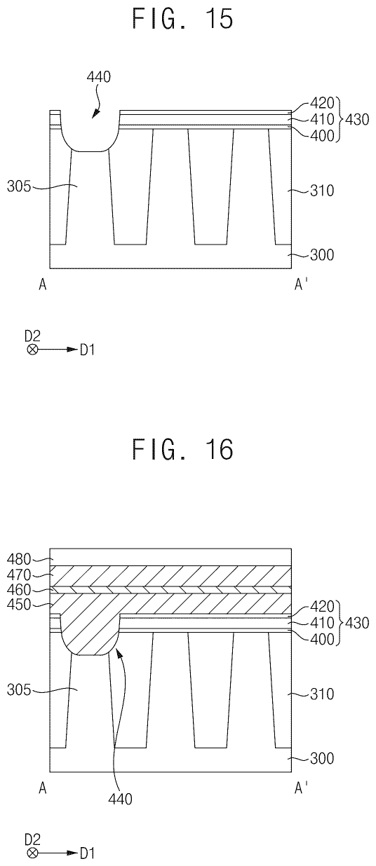

Referring to FIGS. 17 and 18, a second etch stop layer and a first capping layer may be sequentially formed on the conductive structure layer, the first capping layer may be etched to form a first capping pattern 585, and the second etch stop layer, the first mask layer 480, the second conductive layer 470, the first barrier layer 460 and the first conductive layer 450 may be sequentially etched using the first capping pattern 585 as an etch mask.

In example embodiments, the first capping pattern 585 may extend lengthwise in the second direction D2, and a plurality of first capping patterns 585 may be spaced apart from each other in the first direction D1.

By the etching process, a second conductive pattern 455, a first barrier pattern 465, a third conductive pattern 475, a first mask 485, a second etch stop pattern 565 and the first capping pattern 585 may be formed on the fourth opening 440, and a third insulation pattern 425, the second conductive pattern 455, the first barrier pattern 465, the third conductive pattern 475, the first mask 485, the second etch stop pattern 565 and the first capping pattern 585 may be sequentially stacked on the third insulating layer 410 of the insulating layer structure 430 at an outside of the fourth opening 440.

Hereinafter, the second conductive pattern 455, the first barrier pattern 465, the third conductive pattern 475, the first mask 485, the second etch stop pattern 565 and the first capping pattern 585 sequentially stacked may be referred to as a bit line structure 595. The second conductive pattern 455, the first barrier pattern 465 and the third conductive pattern 475 may form a conductive structure, and the first mask 485, the second etch stop pattern 565 and the first capping pattern 585 may form an insulating structure. In example embodiments, the bit line structure 595 may extend lengthwise in the second direction D2, and a plurality of bit line structures 595 may be spaced apart from each other in the first direction D1.

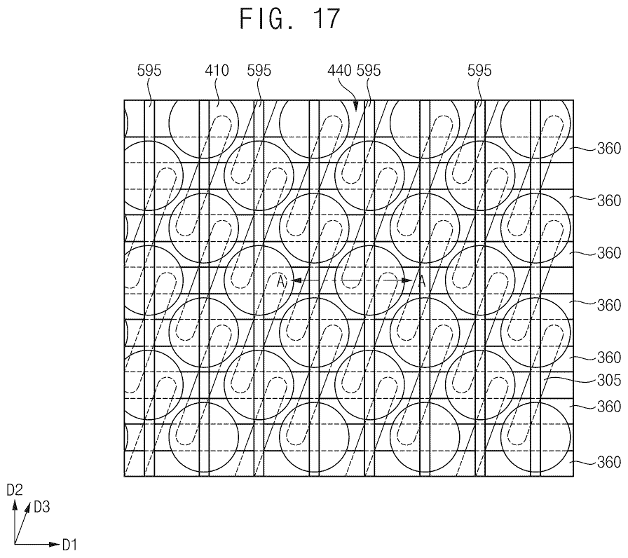

Referring to FIG. 19, a first spacer layer may be formed on the substrate 300 on which the bit line structure 595 is formed, and fourth and fifth insulating layers may be sequentially formed on the first spacer layer.

The first spacer layer may also cover a sidewall of the third insulation pattern 425 under the bit line structure 595 on the second insulating layer 410, and the fifth insulating layer may fill a remaining portion of the fourth opening 440.

The fourth and fifth insulating layers may be etched by an etching process. In example embodiments, the etching process may be a wet etching process using, for example, phosphoric acid (H₂PO₃), SC1, and hydrofluoric acid (HF) as an etchant, and portions of the fourth and fifth insulating layers except for portions thereof in the fourth opening 440 may be removed. Thus, most portion of a surface of the first spacer layer, that is, all portions of the surface of the first spacer layer except for a portion of the surface thereof in the fourth opening 440 may be exposed, and the fourth and fifth insulating layers remaining in the fourth opening 440 may form fourth and fifth insulation patterns 610 and 620, respectively.

A second spacer layer may be formed on the exposed surface of the first spacer layer and the fourth and fifth insulation patterns 610 and 620 in the fourth opening 440. The second spacer layer may be anisotropically etched to form a second spacer 630 covering a sidewall of the bit line structure 595 on the surface of the first spacer layer and on the fourth and fifth insulation patterns 610 and 620.

A dry etching process may be performed using the first capping pattern 585 and the second spacer 630 as an etch mask to form a fifth opening 640 exposing an upper surface of the active pattern 305, and upper surfaces of the isolation pattern 310 the gate mask 350 may also be exposed by the fifth opening 640.

By the dry etching process, portions of the first spacer layer on upper surfaces of the first capping pattern 585 and the second insulating layer 410 may be removed, and thus a first spacer 600 may be formed on the sidewall of the bit line structure 595. By the dry etching process, the first and second insulating layers 400 and 410 may be partially removed to remain as first and second insulation patterns 405 and 415, respectively, under the bit line structure 595. The first to third insulation patterns 405, 415 and 425 sequentially stacked under the bit line structure 595 may form a first insulation pattern structure 435.

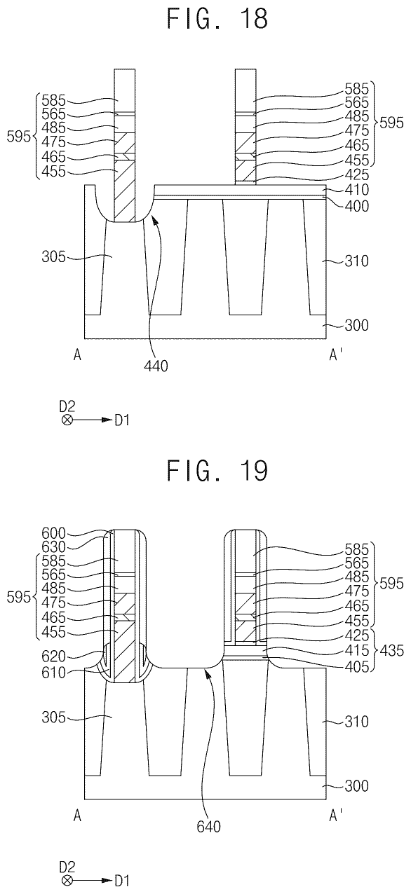

Referring to FIG. 20, a third spacer layer may be formed on an upper surface of the first capping pattern 585, an outer sidewall of the second spacer 630, portions of the upper surfaces of the fourth and fifth insulation patterns 610 and 620, and upper surfaces of the active pattern 305, the isolation pattern 310 and the gate mask 350 exposed by the fifth opening 640. The third spacer layer may be anisotropically etched to form a third spacer 650 covering the sidewall of the bit line structure 595.

The first to third spacers 600, 630 and 650 sequentially stacked on the sidewall of the bit line structure 595 in the horizontal direction may be referred to as a preliminary spacer structure 660.

A sacrificial layer may be formed to fill the fifth opening 640 on the substrate 300 to a sufficient height, and an upper portion of the second sacrificial layer may be planarized until the upper surface of the first capping pattern 585 is exposed to form a sacrificial pattern 680 in the fifth opening 640.

In example embodiments, the sacrificial pattern 680 may extend in the second direction D2, and a plurality of sacrificial patterns 680 may be spaced apart from each other in the first direction D1 by the bit line structures 595. The sacrificial pattern 680 may include an oxide, e.g., silicon oxide.

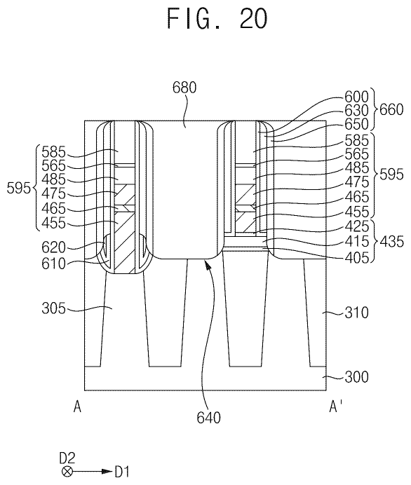

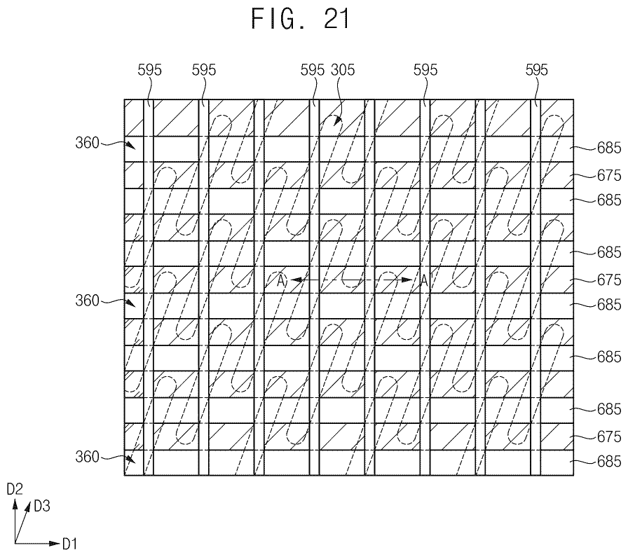

Referring to FIGS. 21 and 22, a second mask including a plurality of sixth openings, each of which may extend lengthwise in the first direction D1, spaced apart from each other in the second direction D2 may be formed on the first capping pattern 585, the sacrificial pattern 680 and the preliminary spacer structure 660, and the sacrificial pattern 680 may be etched using the second mask as an etching mask.

In example embodiments, each of the sixth openings may overlap a region between the gate structures 360 in the vertical direction. By the etching process, a seventh opening exposing upper surfaces of the active pattern 305 and the isolation pattern 310 may be formed between the bit line structures 595 on the substrate 300.

The second mask may be removed, a lower contact plug layer may be formed to fill the seventh opening to a sufficient height, and an upper portion of the lower contact plug layer may be planarized until the upper surface of the first capping pattern 585 and upper surfaces of the sacrificial pattern 680 and the preliminary spacer structure 660 are exposed. Thus, the lower contact plug layer may be transformed into a plurality of lower contact plugs 675 spaced apart from each other in the second direction D2 between the bit line structures 595. Additionally, the sacrificial pattern 680 extending in the second direction D2 between the bit line structures 595 may be divided into a plurality of parts in the second direction D2 by the lower contact plugs 675.

The sacrificial pattern 680 may be removed to form an eighth opening, and a second capping pattern 685 may be formed to fill the eighth opening. In example embodiments, the second capping pattern 685 may overlap the gate structure 360 in the vertical direction.

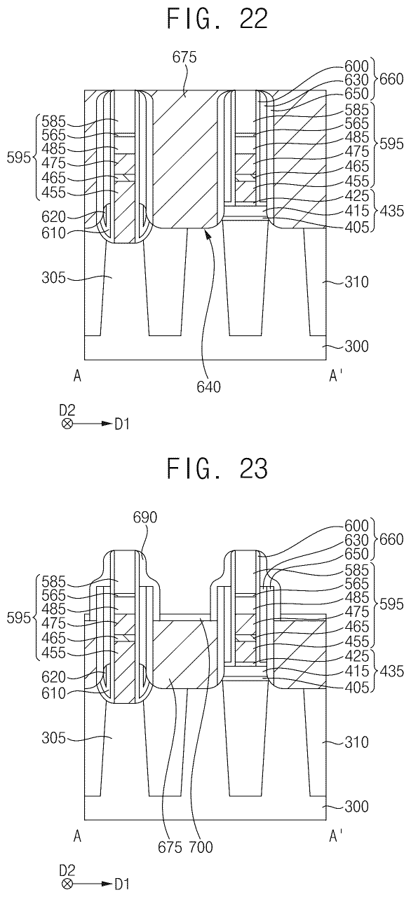

Referring to FIG. 23, an upper portion of the lower contact plug 675 may be removed to expose an upper portion of the preliminary spacer structure 660 on the sidewall of the bit line structure 595, and upper portions of the second and third spacers 630 and 650 of the exposed preliminary spacer structure 660 may be removed.

An upper portion of the lower contact plug 675 may be additionally removed. Thus, an upper surface of the lower contact plug 675 may be lower than upper surfaces of the second and third spacers 630 and 650.

A fourth spacer layer may be formed on the bit line structure 595, the preliminary spacer structure 660, the second capping pattern 685 and the lower contact plug 675, and may be anisotropically etched to form a fourth spacer 690 covering an upper portion of the preliminary spacer structure 660 on the sidewall of the bit line structure 595, and the upper surface of the lower contact plug 675 may be exposed by the etching process.

A metal silicide pattern 700 may be formed on the exposed upper surface of the lower contact plug 675. In example embodiments, the metal silicide pattern 700 may be formed by forming a first metal layer on the first and second capping patterns 585 and 685, the fourth spacer 690 and the lower contact plug 675, performing a heat treatment thereon, and removing an unreacted portion of the first metal layer.

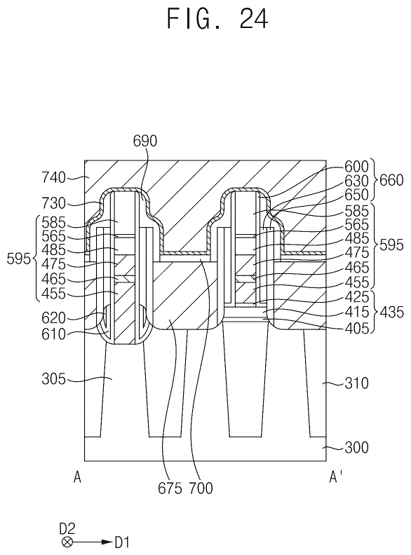

Referring to FIG. 24, a second barrier layer 730 may be formed on the first and second capping patterns 585 and 685, the fourth spacer 690, the metal silicide pattern 700 and the lower contact plug 675, and a second metal layer 740 may be formed on the second barrier layer 730 to fill a space between the bit line structures 595.

A planarization process may be performed on an upper portion of the second metal layer 740. The planarization process may include, for example, a chemical mechanical polishing (CMP) process and/or an etch-back process.

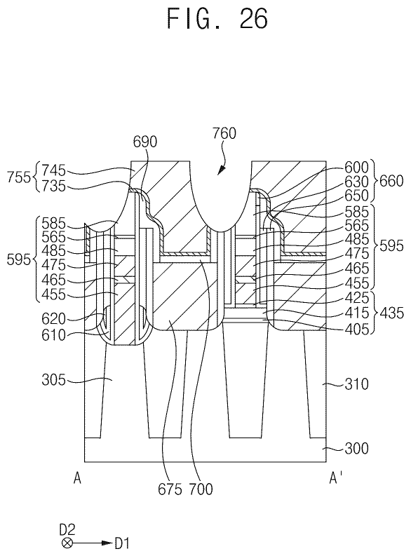

Referring to FIGS. 25 and 26, the second metal layer 740 and the second barrier layer 730 may be patterned to form an upper contact plug 755. In example embodiments, a plurality of upper contact plugs 755 may be formed, and a ninth opening 760 may be formed between the upper contact plugs 755.

The ninth opening 760 may be formed by partially removing the first and second capping patterns 585 and 685, the preliminary spacer structure 660 and the fourth spacer 690 as well as the second metal layer 740 and the second barrier layer 730.

The upper contact plug 755 may include a second metal pattern 745 and a second barrier pattern 735 covering a lower surface of the second metal pattern 745. In example embodiments, the upper contact plug 755 may have a shape of a circle, an ellipse, or a rounded polygon in a plan view, and the upper contact plugs 755 may be arranged, for example, in a honey comb pattern in the first and second directions D1 and D2, in a plan view.

The lower contact plug 675, the metal silicide pattern 700 and the upper contact plug 755 sequentially stacked on the substrate 300 may collectively form a contact plug structure.

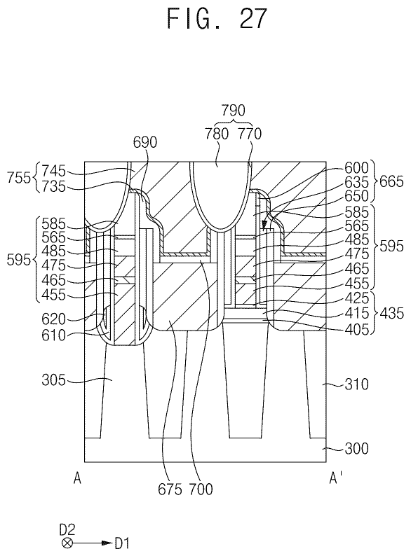

Referring to FIG. 27, the second spacer 630 included in the preliminary spacer structure 660 exposed by the ninth opening 760 may be removed to form an air gap, a sixth insulation pattern 770 may be formed on a bottom and a sidewall of the ninth opening 760, and a seventh insulation pattern 780 may be formed to fill a remaining portion of the ninth opening 760.

Each of the sixth and seventh insulation patterns 770 and 780 may form a second insulation pattern structure 790.

An upper end of the air gap may be covered by the sixth insulation pattern 770, and thus an air spacer 635 may be formed. The first spacer 600, the air spacer 635 and the third spacer 650 may form a spacer structure 665.

Referring back to FIGS. 10 and 11, the capacitor, the first etch stop layer 30, the support layer 50 and the upper electrode plate 120 may be formed by processes substantially the same as or similar to the processes illustrated with reference to FIGS. 1 to 9.

The lower electrode structure 77 included in the capacitor may contact an upper surface of the upper contact plug 755.

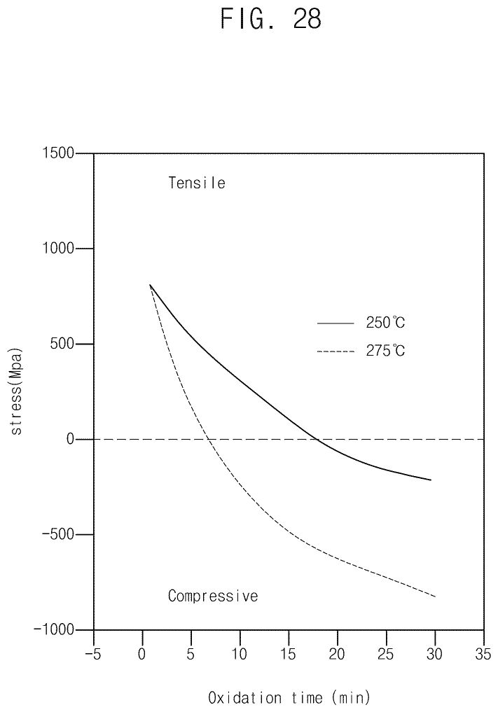

FIG. 28 is a graph illustrating changes in stress magnitude over time when an oxide layer is formed on a surface of a titanium nitride layer.

Referring to FIG. 28, as an oxidation process is performed on the surface of the titanium nitride layer, tendency of changes of the stress of the titanium nitride layer from a tensile stress to a compressive stress is observed.

Specifically, each of the titanium nitride layers at a temperature of about 250° C. and at a temperature of about 275° C., respectively, may have a tensile stress of about 750 MPa before the oxidation process. As the oxidation process is performed on the titanium nitride layers, the stress of each of the titanium nitride layers at a temperature of about 250° C. and at a temperature of about 275° C., respectively, changes from a tensile stress to a compressive stress at a temperature of about 7 minutes and at a temperature of about 17 minutes, respectively.

As an oxide layer is formed on a surface of the titanium nitride layer, the initial tensile stress may change to the compressive stress. Thus, a lower electrode including titanium nitride may bend due to the difference between the tensile stress and the compressive stress.

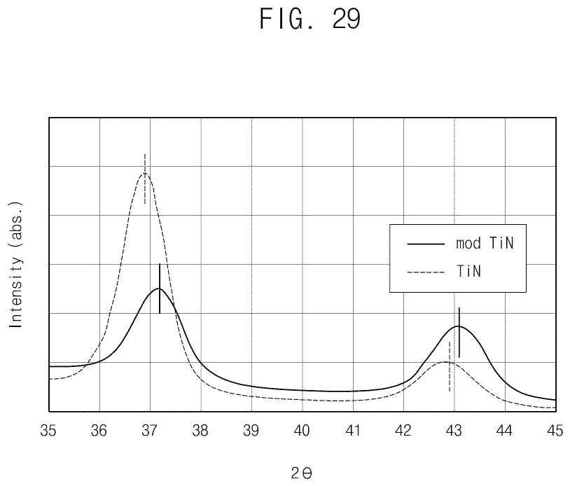

FIG. 29 is a graph showing XRD (X-ray Diffraction) experimental results for a titanium nitride layer according to a comparative example and a titanium nitride layer including an insertion layer and/or an insertion pattern according to example embodiments. The graph for the titanium nitride layer according to the comparative example is indicated by a dotted line, while the graph for the titanium nitride layer according to the example embodiments is indicated by a solid line.

Referring to FIG. 29, when compared to the titanium nitride layer according to the comparative example, a peak of the titanium nitride layer according to the example embodiments is shifted to the right, which may indicate that a lattice constant in the titanium nitride layer according to example embodiments is smaller.

By applying values from the graph to Bragg's law (nλ=2d sin θ), a lattice constant of the titanium nitride layer according to the comparative example is about 4.24 Å, while the lattice constant of the titanium nitride layer according to the example embodiments is about 4.15 Å, which may indicate that the tensile stress of the titanium nitride layer according to the example embodiments is smaller.

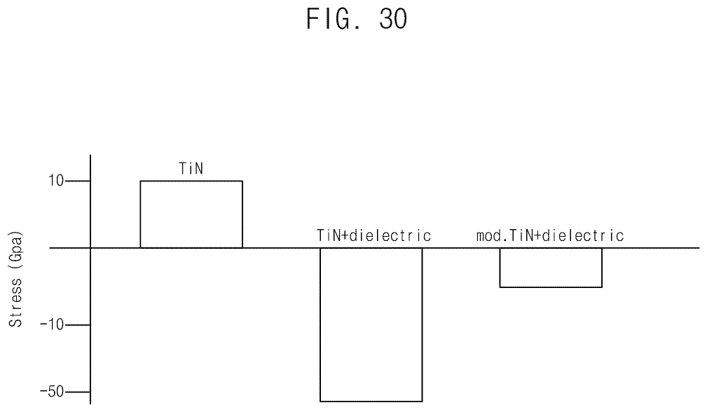

FIG. 30 is a bar graph showing a stress of titanium nitride layers with a dielectric layer on a surface of the titanium nitride layer according to a comparative example and the titanium nitride layer according to example embodiments.

Referring to FIG. 30, the titanium nitride layer according to the comparative example has a tensile stress of about 10 GPa without a dielectric layer on a surface thereof, while the titanium nitride layer has a compressive stress of about 50 GPa with the dielectric layer on the surface thereof.

In contrast, the titanium nitride layer according to the example embodiments has a compressive stress of about 10 GPa with the dielectric layer on a surface thereof. This may indicate that the initial tensile stress of the titanium nitride layer according to the example embodiments is reduced, resulting in a reduced compressive stress after the dielectric layer is formed.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A capacitor structure, comprising:
a lower electrode structure comprising:
a lower electrode including a first material containing a metal and extending in a first direction; and
an insertion layer including a second material having a coefficient of thermal expansion (CTE) lower than a CTE of the first material and extending in the first direction through the lower electrode;
a dielectric pattern on a surface of the lower electrode structure; and
an upper electrode on a surface of the dielectric pattern.

2. The capacitor structure of claim 1, wherein the first material includes TiN, and the second material includes at least one of SiO₂, Al₂O₃, Ta₂O₃, Nb₂O₅, ZnO, ZrO₂, HfO₂, MgO, SiN, SiC, AlN, HfN, and WC.

3. The capacitor structure of claim 1, wherein the lower electrode structure further includes insertion patterns dispersed in the lower electrode, each of the insertion patterns including the second material.

4. The capacitor structure of claim 1, wherein the insertion layer is one of a plurality of insertion layers spaced apart from each other in a second direction crossing the first direction.

5. The capacitor structure of claim 1, wherein a thickness of the insertion layer in a second direction crossing the first direction is in a range of about 1 Å to about 10 Å.

6. The capacitor structure of claim 1, wherein the CTE of the second material is less than about 8*10⁻⁶/K.

7. The capacitor structure of claim 1, wherein a weight ratio of the insertion layer with respect to the lower electrode structure is less than about 30%.

8. The capacitor structure of claim 1, further comprising an interface layer including an oxide, the interface layer being disposed between and contacting a sidewall of the lower electrode structure and a sidewall of the dielectric pattern.

9. A capacitor structure, comprising:
a lower electrode structure comprising:
a lower electrode including a first material and extending in a first direction; and
an insertion layer including a second material including a central atom having an ionic radius smaller than an ionic radius of a central atom of the first material, the insertion layer extending in the first direction through the lower electrode;
a dielectric pattern on a surface of the lower electrode structure; and
an upper electrode on a surface of the dielectric pattern.

10. The capacitor structure of claim 9,
wherein the central atom of the first material is Ti, and
wherein the second material includes at least one of V, Cr, Mn, Fe, Ga, Ge, Al, Si, Mg, Mo and Ru.

11. The capacitor structure of claim 9, wherein the ionic radius of the central atom of the second material is less than about 0.7 Å.

12. The capacitor structure of claim 9, wherein the lower electrode structure further comprises insertion patterns including the second material and dispersed in the lower electrode.

13. The capacitor structure of claim 9, wherein the insertion layer is one of a plurality of insertion layers spaced apart from each other in a second direction crossing the first direction.

14. The capacitor structure of claim 9, wherein a thickness of the insertion layer in a second direction crossing the first direction is in a range of about 1 Å to about 10 Å.

15. The capacitor structure of claim 9, wherein a weight ratio of the insertion layer with respect to the lower electrode structure is less than about 30%.

16. The capacitor structure of claim 9, further comprising an interface layer including an oxide, the interface layer being disposed between and contacting a sidewall of the lower electrode structure and a sidewall of the dielectric pattern.

17. A semiconductor device, comprising:
an active pattern on a substrate;
a gate structure at an upper portion of the active pattern, the gate structure extending in a first direction substantially parallel to an upper surface of the substrate;
a bit line structure on a middle portion of the active pattern, the bit line structure extending in a second direction substantially parallel to the upper surface of the substrate and crossing the first direction;
a contact plug structure on each of opposite ends of the active pattern; and
a capacitor structure on the contact plug structure, the capacitor structure comprising:
a lower electrode structure comprising:
a lower electrode including a first material containing a metal and extending in the first direction; and
a plurality of insertion patterns including a second material having a CTE lower than a CTE of the first material or a third material including a central atom having an ionic radius smaller than an ionic radius of a central atom of the first material, the plurality of insertion patterns being dispersed in the lower electrode;
a dielectric pattern on a surface of the lower electrode structure; and
an upper electrode on a surface of the dielectric pattern.

18. The semiconductor device of claim 17, wherein the first material includes TiN, and the second material includes at least one of SiO₂, Al₂O₃, Ta₂O₃, Nb₂O₅, ZnO, ZrO₂, HfO₂, MgO, SiN, SiC, AlN, HfN, and WC.

19. The semiconductor device of claim 17, wherein the CTE of the second material is lower than about 8*10⁻⁶/K.

20. The semiconductor device of claim 17, wherein:
the central atom of the first material is Ti,
the third material includes at least one of V, Cr, Mn, Fe, Ga, Ge, Al, Si, Mg, Mo and Ru, and
the ionic radius of the central atom of the third material is less than about 0.7 Å.
